(19) United States
(12) Patent Application Publication
(10) Pub. No.: US 2008/0050680 A1
(43) Pub. Date: Feb. 28, 2008

(54) Lithography systems and methods

(76) Inventor: Stefan Brandl, Albany, NY (US)

Correspondence Address: SLATER & MATSIL LLP, 17950 PRESTON ROAD, SUITE 1000, DALLAS, TX, 75252, US

(21) Appl. No.: 11/509,367

(22) Filed: Aug. 24, 2006

(51) Int. Cl. G03F 7/20

(52) U.S. Cl. 430/394; 430/311; 430/396

(57) ABSTRACT

Systems and methods of lithography of semiconductor devices are disclosed. A preferred embodiment comprises a method of exposing a workpiece. The method includes moving a workpiece along a plurality of exposure fields in a column in a first direction while alternatingly moving a lithography mask in a second direction and the first direction for the plurality of exposure fields in the column. The second direction comprises a direction opposite the first direction.

### TECHNICAL FIELD

The present invention relates generally to the fabrication of semiconductor devices, and more particularly to lithography systems and methods used to fabricate semiconductor devices.

### BACKGROUND

Generally, semiconductor devices are manufactured by depositing many different types of material layers over a semiconductor workpiece or wafer. The material layers are patterned using lithography. The material layers typically comprise thin films of conductive, semiconductive, and insulating materials that are patterned and etched to form integrated circuits (IC's).

For many years in the semiconductor industry, optical lithography techniques such as contact printing, proximity printing, and projection printing have been used to pattern material layers of integrated circuits. Projection printing is commonly used in the semiconductor industry using wavelengths of 248 nm or 193 nm, as examples. At such wavelengths, lens projection systems and transmission lithography masks are used for patterning, wherein light is passed through the lithography mask to impinge upon a wafer.

However, as the minimum feature sizes of IC's are decreased, the semiconductor industry is exploring the use of alternatives to traditional optical lithography techniques, in order to meet the demand for decreased feature sizes in the industry. For example, short wavelength lithography techniques such as Extreme Ultraviolet (EUV) Lithography, electron beam based lithography technologies, other non-optical lithographic techniques, and immersion lithography are under development as replacements for traditional optical lithography techniques.

In immersion lithography, the gap between the last lens element in the optics system and a semiconductor wafer is filled with a liquid, such as water, to enhance system performance. The presence of the liquid enables the index of refraction in the imaging plane, and therefore the numerical aperture of the projection system, to be greater than unity. Thus, immersion lithography has the potential to extend exposure tool minimum feature sizes down to about 45 nm or less, for example.

However, because immersion lithography is relatively new in the industry, there are several problems and issues that need to be resolved before the technology is ready to be implemented in full scale production. For example, one problem is that traditional scanning methods tend to leave watermarks on the surface of a semiconductor device, which can lead to defects in the semiconductor devices formed.

Thus, what are needed in the art are improved scanning methods for use in immersion lithography systems.

### SUMMARY OF THE INVENTION

These and other problems are generally solved or circumvented, and technical advantages are generally achieved, by preferred embodiments of the present invention, which provide novel scanning methods for lithography.

In accordance with a preferred embodiment of the present invention, a method of exposing a workpiece includes moving a workpiece along a plurality of exposure fields in a column in a first direction while alternatingly moving a lithography mask in a second direction and the first direction for the plurality of exposure fields in the column. The second direction comprises a direction opposite the first direction.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is an illustration of a typical conventional scan movement in a lithography system during an exposure process;

FIG. 2 shows centrifugal forces on a wafer stage due to conventional motion paths used during scanning processes;

FIG. 3 shows a motion path in accordance with a preferred embodiment of the present invention;

FIG. 4 is a graph showing a wafer stage velocity and acceleration during the motion path of the embodiment of the present invention shown in FIG. 3;

FIG. 5 shows reduced centrifugal forces on a wafer stage due to the motion path of the embodiment of the present invention shown in FIG. 3;

FIG. 6 is a top view of a motion path across an entire wafer in accordance with a preferred embodiment of the present invention;

FIG. 7 illustrates movement of a wafer stage and reticle stage in accordance with a preferred embodiment of the invention;

FIG. 8 shows an example of scanning a plurality of exposure fields arranged in rows and columns in accordance with an embodiment of the present invention; and

FIG. 9 shows a lithography system in accordance with a preferred embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely methods of scanning in lithography for semiconductor devices that are implementable in immersion lithography systems. The scanning methods of embodiments of the invention may also be applied, however, to other types of lithography systems used to pattern material layers of semiconductor devices, for example.

In earlier generation lithography processes, an entire lithography mask was exposed on an exposure field of a wafer at once. However, if a large field is exposed through a projection lens, distortions may occur at the edge of the pattern. Therefore, more recent generations of lithography systems and processes expose only a portion of a lithography mask through a slit in an opaque plate, using a smaller portion of the lens, e.g., the “sweet spot” of the lens of the projection lens system.

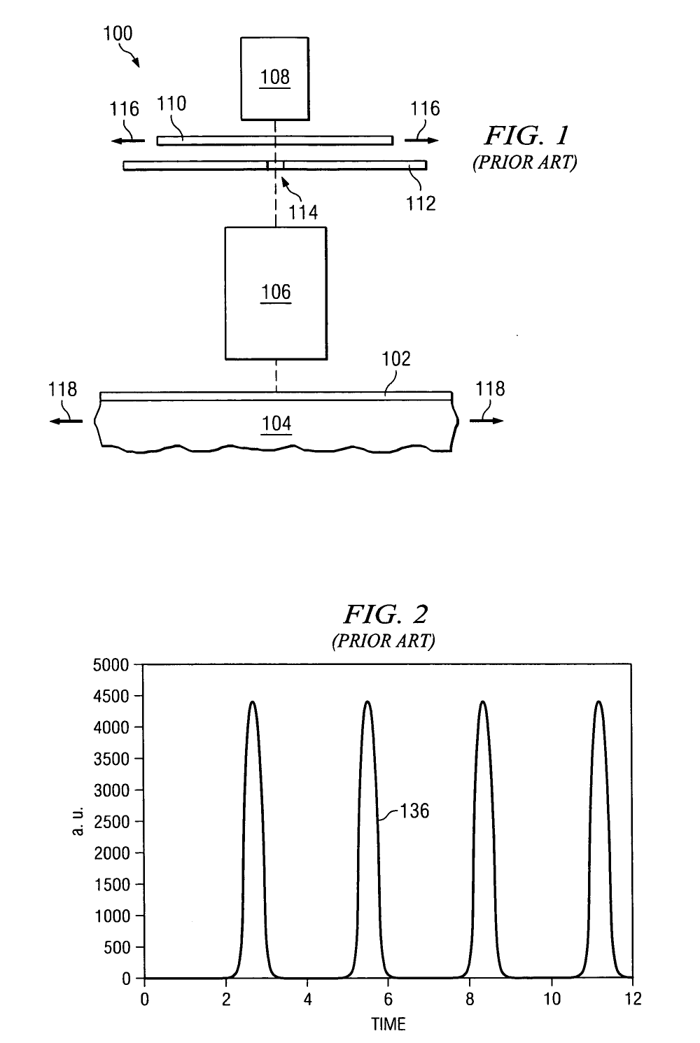

With reference now to FIG. 1, there is shown an illustration of a conventional scan movement in a lithography system 100 during an exposure process. A wafer support 104 is adapted to hold a wafer 102 and is located proximate one end of a projection lens system 106. An illuminator 108 is disposed proximate the opposite end of the projection lens system 106 from the wafer support 104. A lithography mask 110 or reticle is disposed between the projection lens system 106 and the illuminator 108, as shown. An opaque plate 112 with a slit 114 therein is disposed between the mask 110 and the projection lens system 106, as shown. Only a small portion of the mask 110 pattern is used to expose the wafer 102 at a time through the slit 114, e.g., in a scanning process.

The movement of the mask 110 and the wafer stage 104 is shown at 116 and 118, respectively. The mask 110 movement 116 and the wafer 102 movement 118 are synchronized. During the scanning process to expose a photosensitive material (not shown) such as a layer of photoresist disposed on the wafer 102, the movement 116 of the mask 110 is typically in an opposite direction of the movement 118 of the wafer 102 and wafer stage, although the mask 110 and wafer 102 may also be moved in the same direction, for example. In some lithography systems 100, for example, the mask 110 is moved about four times faster than the wafer 102 is moved.

Lithography exposure tools or systems 100 are used to expose a mask 110 image into a photosensitive polymer layer, referred to as a resist or photoresist on the wafer 102. The pattern of the mask 110 is projected onto the wafer 102 through a projection optic or projection lens system 106 that reduces the size of the image of the mask 110 by a factor of four, in some applications. Typical exposure field sizes at the wafer 102 level are often about 30 mm×20 mm in some applications, as an example. A single exposure field may comprise a single die or a plurality of die, for example.

To cover the entire surface of the wafer 102, which may have a diameter of about 300 mm, as an example, the wafer 102 disposed on the wafer stage 104 is moved below the projection lens 106 in the required steps, e.g., by about 20 mm. In scanners, the mask 110 is not imaged as a whole at once, rather, the mask 110 is placed above a slit 114 in the opaque plate 112 and only the slit 114 area is projected onto the wafer 102. In order to print the entire mask 110, the mask 110 is moved or scanned across the slit 114 in a direction 116, while the wafer 102 on the other side of the projection lens 106 is moved in the other direction 118 that is opposite direction 116. The slit 114 is used to improve lens aberrations of the projection lens system 106, for example.

In conventional motion paths, the wafer stage 104 shown in FIG. 1 is moved in a meandering path beneath an exposure slit 114 during an exposure process. Moving from one exposure field to another in the x-direction and scanning across each exposure field on the wafer 102 in the y-direction results in a complicated step and scan motion of the wafer stage 104 involving many acceleration and deceleration steps. For example, a motion path for the wafer 102 and wafer stage 104 may begin in an upper left corner of a wafer 102 and continue downward in a y-direction through an overscan region proximate (e.g., above) an exposure field. The exposure field is then scanned, e.g., downwardly in the y-direction, during an exposure process. The motion path is continued downwardly through another overscan region proximate (e.g., below) the exposure field, and the wafer stage 104 is then moved in a meandering path at a sharp angle in an x and y direction in order to step from one column to the other within the same row, e.g., in a stepping region. The motion path then is continued upward vertically in the y-direction through an overscan region proximate the next exposure field, where an exposure process is performed. The motion path then continues upwardly in the y-direction through another overscan region, after which the motion path for the wafer 102 is again stepped in the x and y direction from one column to the next, in another stepping region. Conventional motion paths are repeated for each row of the exposure fields, alternating the exposure process from up to down and down to up through the exposure fields in each row. After a row is completed, the process is repeated until the exposure fields in all rows have been exposed.

Conventional motion paths are problematic in several respects. First, the overscan regions and the stepping regions represent wasted movement of the motion path, and thus comprise wasted time on the exposure tool or lithography system 100. However, because of the sharp and irregular radius of the curves and angles taken by the motion path of the workpiece 102, the overscan region on either side of the exposure field is required for stabilization. Furthermore, a large amount of the motion path is required for the stepping region in order for the motion path to move from one column to the next.

Second, in conventional motion paths, the stepping motion of the motion path of the workpiece 102 has a small turning radii and high centrifugal forces, e.g., in the stepping region. The stepping motion of the motion path also has a varying radius. For example, in the stepping region, the radius is smaller at first and then grows larger, resulting in an asymmetric path within the stepping region. Once the stepping region is reached, the motion path moves at about a 45 degree angle, and makes a sharp turn at about 90 degrees, for example.

Third, the motion path of the workpiece 102 involves increasing and decreasing the velocity of the motion path. Especially in immersion lithography, where water is applied between the projection lens system 106 and a layer of resist on a wafer 102, acceleration involves forces on the liquid contained below the lens system 106 that are believed to lead to a failure of the water containment, causing water to be left on the resist layer of the wafer 102, which leads to defects and device failures. Other factors may also contribute to the formation of watermarks and water damage, for example.

Another problem with the meandering path of the motion path is that during acceleration phases, vibrations on the wafer stage 104 occur, leading to problems in aligning layers on top of each other, e.g., of multiple material layers formed on the semiconductor device or wafer 102.

While the velocity and the acceleration of the motion path are kept constant during the exposure process and through the overscan region, in the stepping regions of conventional motion paths, the velocity and acceleration fluctuate and vary by a large amount. The wafer stage 104 speed or velocity changes during the stepping motion, e.g., in the stepping region of the motion path, which implicates a strong amount of acceleration. Defects have been correlated to the peaks that indicate a change in the acceleration phase of the motion path of conventional semiconductor devices, for example.

FIG. 2 shows centrifugal forces 136 on the wafer stage 104 due a conventional motion path. The centrifugal forces 136 during the stepping region, e.g., at a time before time=6 seconds, show a large amount of centrifugal force 136, e.g., over 4,000 in arbitrary units (a.u.). Thus, conventional motion paths have a large amount of centrifugal force 136 during the stepping process. The centrifugal force 136 affects parts of the scanner, e.g., the wafer stage 104 and also the wafer 102 being patterned.

In immersion lithography systems, the peaks in the centrifugal force 136 have been correlated with water being left on a semiconductor device, which results in watermarks and defects on the device, for example. Referring again to FIG. 1, to pattern an entire wafer 102 using conventional processes, many step motions are used; e.g., the wafer 102 is moved up and down during the scanning process, and in-between up-scans and down-scans, the wafer 102 is stepped along a row. The mask 110 is simultaneously scanned up and down over the exposure slit 114, exposing an exposure field of the wafer 102 during each scan. For example, the motion path 120 of the wafer stage 104 starts at the middle of the bottom of the wafer 102, moves up during the exposure process, steps over to the right, then down during the exposure process for the adjacent exposure field, and continues to the right until all exposure fields have been exposed on that particular row. Then the process is repeated for the next row, and the next row, until the end is reached. Note that at every sharp turn of the motion path, there is a high probability of a watermark being left on a semiconductor device, in an immersion lithography system, for example.

Thus, conventional scanning methods are time-consuming and require a large amount of overscan regions and time, and require a large amount of time for stepping over to the next exposure field. A large amount of velocity and acceleration changes and centrifugal force occurs during the stepping regions, which can cause the formation of watermarks in immersion lithography systems, for example. Furthermore, high amounts of centrifugal force in the stepping process can result in misalignment of material layers of the semiconductor device being manufactured, e.g., if the wafer 102 is caused to slip within the wafer support 104, as one example.

Embodiments of the present invention achieve technical advantages by providing novel scanning methods that do not have large amounts of changes in the velocity or acceleration of the wafer stage during a stepping motion. Rather, in some embodiments, the stepping movement comprises a maximum constant radius, and is performed at a constant speed and/or acceleration, to be described further herein. In other embodiments, entire columns are exposed at once, reducing the number of stepping movements.

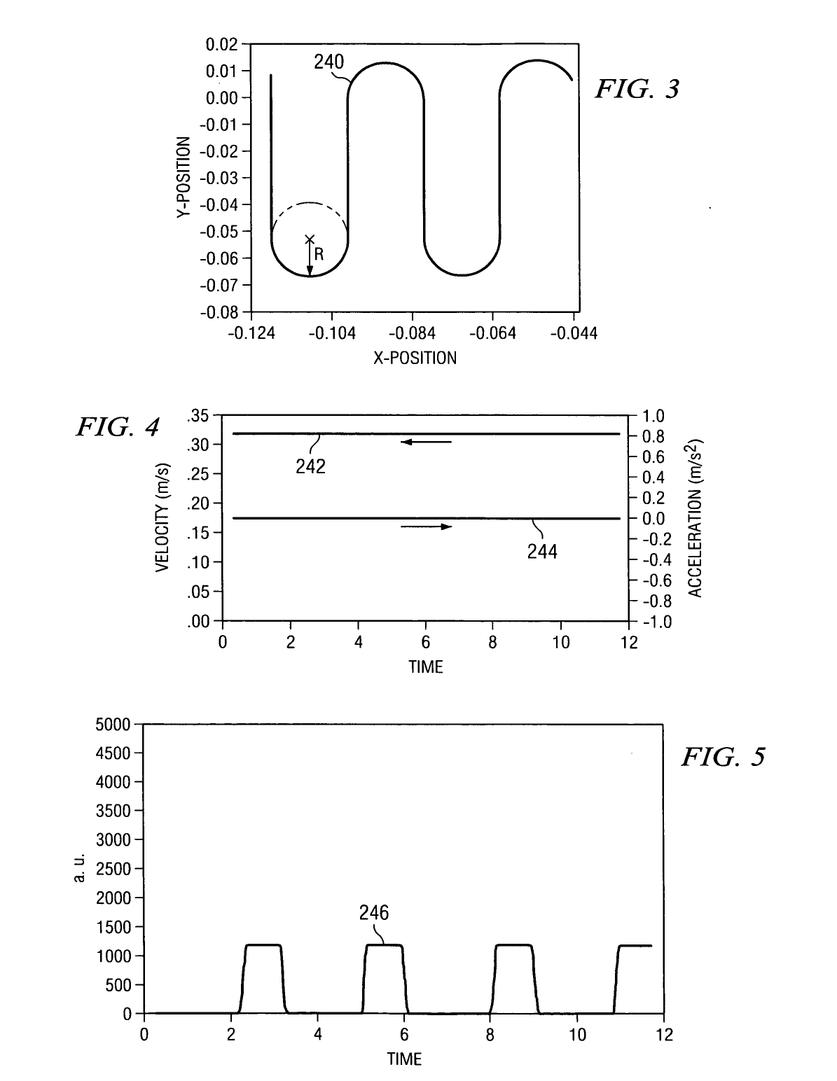

FIG. 3 shows a novel motion path 240 for a scanning process in accordance with an embodiment of the present invention that achieves wafer stage 204 (not shown in FIG. 3; see FIG. 9) acceleration avoidance in lithography exposure tools 280. A novel lithography system 280 in which the novel scanning methods may be implemented is shown in FIG. 9, to be described further herein. By using a constant radius R (see FIG. 3) in the stepping process from one column to an adjacent column and a constant speed of the wafer support 204 movement, acceleration is minimized during the scanning process.

The motion path 240 shown illustrates the movement of a wafer stage 204 beneath an exposure slit 214 (see FIG. 9) in a scanning process for exposure of a wafer 202 in accordance with a preferred embodiment of the present invention. The wafer stage 204 is moved through at least one exposure field of a column of exposure fields, in accordance with a preferred embodiment of the present invention, during an exposure process. For example, the motion path 240 may be scanned from 0.010 on the y-axis to −0.060 on the y-axis, wherein the range from 0.010 to −0.060 includes at least one exposure field on a semiconductor device 288 (see FIG. 9). After at least one exposure field is scanned and exposed, then the wafer stage 204 is stepped over to the next column, as shown from about −0.124 to −0.104 on the x-axis. The first column may be scanned downwardly and the second column may be scanned upwardly, as shown, although alternatively, the first column may be scanned upwardly and the second column may be scanned downwardly, not shown. The movement of the wafer stage 204 is shown as moving up and down in columns; alternatively, the movement of the wafer stage 204 may be from side to side in rows, for example, not shown.

In some embodiments, only one exposure field is exposed in a column, and then the wafer stage 204 is stepped over to the next adjacent column in the same row, preferably using or at a constant radius R, as shown in FIG. 3, and the exposure field in the adjacent column is scanned and exposed. For example, the stepping motion preferably comprises a circular motion having a radius R that remains constant while stepping to the next adjacent column. The radius R may comprise about 2 to 5 mm, or about 10 mm or less, depending on the application, as examples, although alternatively, the constant radius R of the stepping motion may comprise other dimensions. The constant radius R may comprise a maximum radius between two adjacent exposure fields. The constant radius R may comprise the width of an exposure field divided by 2, as an example. The velocity and/or acceleration of the motion path 240 preferably also remain the same, e.g., remain constant, during the motion path 240 and during the exposure process, in some embodiments, for example. The constant radius R minimizes acceleration during the stepping process, advantageously.

In other embodiments, two or more exposure fields are exposed in each column before the wafer stage 204 is stepped over to an adjacent column, for example. In some embodiments, every exposure field in a column is exposed before the wafer stage 204 is stepped over to an adjacent column, for example, further reducing the number of stepping motions that are required to expose an entire wafer 220, and further reducing changes in velocity and acceleration of the wafer stage 204 during the exposure of an entire column of exposure fields, for example.

In some embodiments, over the motion path 240, exposure of exposure fields is performed on every other exposure field in an entire column, to be described further herein. Not exposing every other field avoids the formation of mirror images of the mask pattern on the fields left unexposed in a column, for example. At the end of each column, the stepping over to the next column is performed, preferably at a constant radius and speed, to minimize the centrifugal force. The motion path 240 is then repeated a second time in an opposite direction, to expose the unexposed fields on the wafer 202, for example.

However, in other embodiments, each exposure field in the column may be exposed during the movement of the motion path 240. Note that in this embodiment, the mask 210 image may be symmetric, so that the reversal of the direction during the exposure during the exposure process results in a repeating pattern being formed on the wafer 202 for all exposure fields in a column, for example. Alternatively, the semiconductor device design may comprise a pattern wherein a repeating pattern for all die or exposure regions is not required, and the repeating pattern may comprise a mirror image for alternating exposure fields in each column, for example.

FIG. 4 is a graph showing wafer stage velocity 242 and acceleration 244 over time during the motion path 240 shown in FIG. 3. Advantageously, the wafer stage 204 is moved at a constant velocity 242 in accordance with embodiments of the present invention; e.g., the wafer stage 204 speed is preferably not altered after the exposure process during the stepping process at the ends of the columns scanned. Thus, advantageously, the acceleration along the motion path 240 is also constant, as shown at 244 in FIG. 4.

FIG. 5 shows centrifugal force 246 on the wafer stage 204 due to the novel motion path 240 shown in FIG. 3, in accordance with an embodiment of the present invention. The centrifugal force 246 would be applied to the water between the semiconductor device and the projection lens system in an immersion lithography system, for example. Although there still remains some centrifugal force 246 during the scanning process, the centrifugal force 246 is significantly reduced compared to the centrifugal force of conventional motion paths, for example. Scanning along a column of exposure fields avoids any acceleration of the wafer stage 204 during the time that the projection lens system 206 (see FIG. 9) is above the wafer 288. Step movement, e.g., motion path 240 shown in FIG. 3 having a constant radius R between scans (e.g., exposures) and at a constant speed results in largely reduced forces acting on the scanner parts, e.g., on the wafer stage 204 and other elements of the lithography system 280.

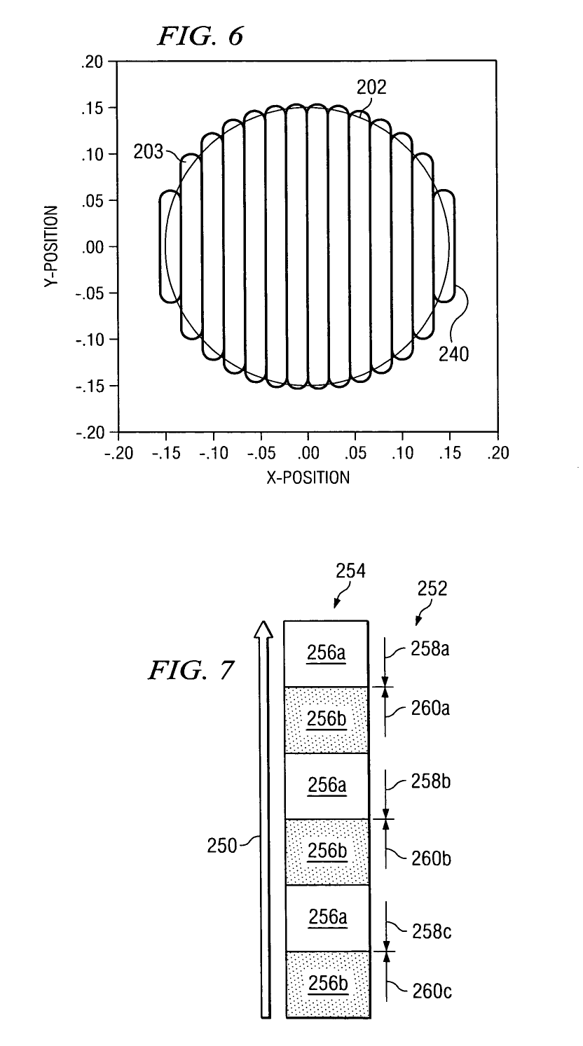

FIG. 6 is a top view of a motion path 240 of a wafer stage 204 across a plurality of exposure fields in columns of a wafer or workpiece 202 (e.g., such as wafer or semiconductor device 288 shown in FIG. 9) in accordance with a preferred embodiment of the present invention. In some embodiments, a plurality of exposure fields in a column is exposed before stepping over to an adjacent column. In the embodiment shown, each column of exposure fields 203 is preferably scanned one column at a time, with a stepping action occurring only at the ends of each column, as shown. The wafer stage 204 is moved along the entire length of each column, one at a time, in a first direction, while the reticle stage is moved alternatingly in the first direction and the second direction. Every other exposure field is exposed, e.g., when the reticle stage is moved in either the first direction or the second direction. The wafer stage 204 is then moved to an adjacent column, and the wafer stage 204 is moved along the entire length of the adjacent column in the second direction while the reticle stage is moved alternatingly in the second direction and the first direction, while exposing every other exposure field. After all columns are scanned of the entire wafer 202, then the motion path 240 is repeated a second time in the opposite direction, and the unexposed exposure fields are exposed in the second motion path 240. Thus, the wafer 202 is scanned twice to expose all exposure fields of the wafer 202 in this embodiment.

In other embodiments, alternatively, portions of the columns may be scanned at a time, not shown. For example, the stepping motion may be performed at a constant radius to move to an adjacent column for another exposure process, not shown. Or, exposure of every exposure field in the columns may be performed, resulting in the formation of mirror images of the mask pattern for every other exposure field in the column.

FIG. 7 illustrates the movement 250 of a wafer stage 204 (see FIG. 9) and the movement 252 of a reticle 210 (or lithography mask—see FIG. 9) stage in accordance with a preferred embodiment of the invention in the exposure of a column 254 of exposure fields 256a and 256b. The wafer stage 204 is moved in a direction 250 at a constant speed, as shown. The wafer stage 204 movement 250 and the reticle 210 movement 252 are coordinated and synchronized so that for alternating exposure fields 256a and 256b in a column, the reticle 210 is moved in a direction 258a opposite direction 250 of the wafer stage 204, and an exposure process takes place on that particular exposure field 256a.

As movement of the wafer stage 204 is continued in the direction 250, the reticle 210 is moved back in the same direction 260a as the direction 250 the wafer stage 204 is moved, during which an exposure process does not take place on that particular exposure field 256b, in some embodiments. Likewise, as movement of the wafer stage 204 continues in the direction 250, the reticle 210 is again moved in a direction 258b opposite direction 250 of the wafer stage 204, and an exposure process is performed on the next exposure field 256a. The movement of the reticle 210 continues in directions 260b, 258c, and 260c as the wafer stage 204 continues to move at a constant speed in direction 250, as shown. The scanning process is repeated a second time to expose the unexposed exposure fields 245b, for example.

Alternatively, in some embodiments, for example, exposure processes may be performed on all exposure regions 256a and 256b during each movement 258a, 260a, 258b, 260b, 258c, and 258c of the reticle 210, so that only one scanning process or motion path 240 (see FIG. 6) is required to expose the entire wafer or semiconductor device 288.

However, in other embodiments of the present invention, a column 254 of exposure fields is scanned twice in order to expose all exposure fields. In these embodiments, after an entire wafer or semiconductor device 288 or column has been exposed a first time using a scanning motion, the wafer 288 or column is scanned a second time, this time with exposure fields 256b that were previously not exposed being exposed alternatingly with exposure fields 256a not being exposed.

Note that in FIG. 7, the exposure process for exposure fields 256a preferably takes place when the wafer 202 is moved in direction 250 that is opposite direction 258a of the movement of the reticle 210. However, alternatively, the exposure process for exposure fields 256a may take place when the wafer 202 is moved in direction 250 that is the same as direction 260a, for example. Likewise, the exposure process for exposure fields 256b may take place when the wafer 202 is moved in direction 250 simultaneously with movement of the reticle 210 in direction 258a that is opposite direction 250, or in direction 260a that is the same as direction 250, for example.

In accordance with an embodiment of the present invention, a method of scanning for a lithography process includes exposing the exposure fields of a workpiece 202 (see FIG. 9) using a lithography mask 210 by moving the workpiece 202 along at least one exposure field in a column for at least one row, stepping over to an adjacent column of exposure fields at a constant radius R (see FIG. 3), and moving the workpiece 202 along at least one exposure field in the adjacent column for at least one row. The method may include moving the workpiece 202 along an entire column of exposure fields in a first direction while alternatingly moving a lithography mask 210 in a second direction and the first direction for each exposure field in the column, wherein the second direction comprises a direction opposite the first direction. The workpiece 202, e.g., a layer of photosensitive material 286 disposed over the workpiece 202, is exposed when the lithography mask 210 is moved in the second direction, and the workpiece 202 is not exposed when the lithography mask 210 is moved in the first direction.

The column of exposure fields may comprise a first column, and the method of scanning may further comprise moving to an adjacent at least one second column after moving the workpiece 202 along the entire first column of exposure fields, and scanning the entire at least one second column in the second direction while alternatingly moving the lithography mask 210 in the first direction and the second direction for exposure fields in the at least one second column. Moving to an adjacent at least one second column is preferably repeated for all columns of the workpiece, alternating moving the workpiece in the first direction and the second direction for each adjacent at least one second column.

After moving the workpiece 202 along the entire column of exposure fields in the first direction while alternatingly moving the lithography mask 210 in the second direction and the first direction for each exposure field in the column, the workpiece 202 may be moved along the entire column of exposure fields in the second direction while alternatingly moving the lithography mask 210 in the first direction and the second direction for each exposure field in the column, exposing the exposure fields that were not exposed when the workpiece was moved in the first direction.

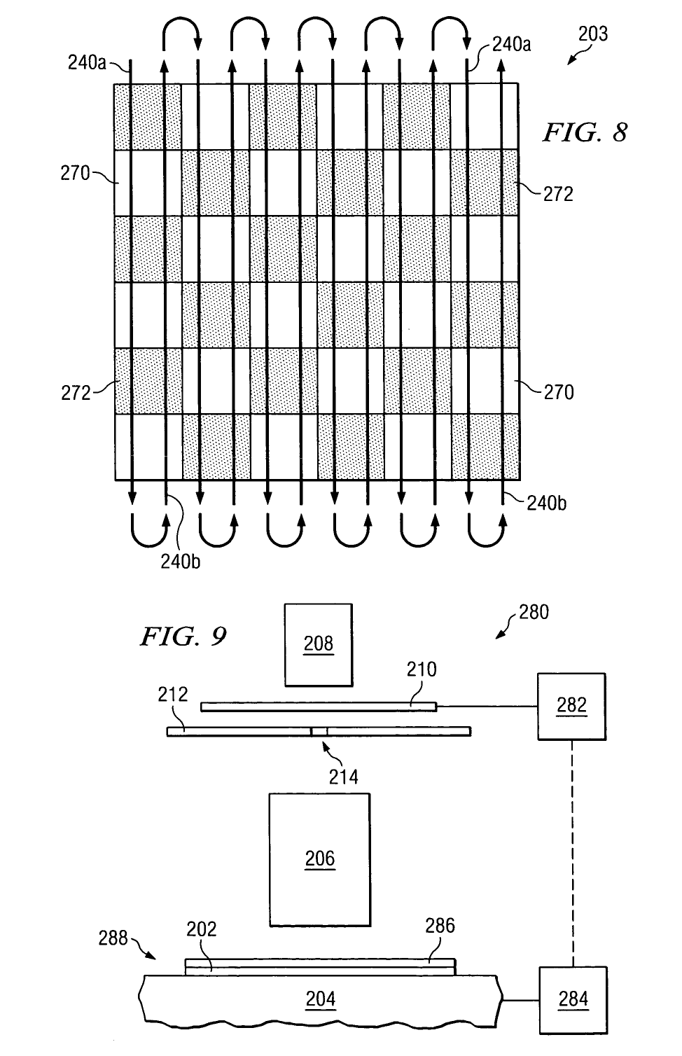

In FIG. 6, the entire wafer 202 may be scanned once to expose every other exposure field on the wafer 202, and the entire wafer 202 is scanned again to expose the remaining unexposed exposure fields. Alternatively, each column may be scanned twice before moving to an adjacent column, exposing alternating exposure fields in the up-scan and the down-scan, as shown in FIG. 8.

FIG. 8 shows an example of scanning a plurality of exposure fields 203 arranged in a matrix of 6×6 exposure fields 203 of rows and columns in accordance with another embodiment of the present invention. Motion paths 240a and 240b represent the motion paths of the wafer stage or support 204 in the movement of the workpiece 202. The motion path 240a starts at the upper left and moves downward. Exposure fields 203 are exposed during an upscan of the wafer stage 204 at 272 and are exposed during a downscan of the wafer stage 204 at 270, alternatingly. Thus, each column of exposure fields is scanned twice, first down, and then up, before the motion path 240b is moved to an adjacent column. The motion path 240b is repeated in the opposite direction to expose the unexposed exposure fields 203 in the column. Each exposure field 203 is scanned twice, once by motion path 240a in a down-scan and again by motion path 240b in an up-scan. After each exposure process, the lithography mask 210 is moved back without exposure, to position the mask 210 in position for the next exposure process.

Note that in FIG. 8, a plurality of exposure fields arranged in rows and columns is shown, wherein the exposure fields in each column are aligned with other exposure fields in the column, and wherein the exposure fields in each row are aligned with other exposure fields in the row. However, the rows and columns may be arranged in other shapes; e.g., the rows and columns of exposure fields may not necessarily be straight, and may not necessarily be arranged at 90 degree angles, not shown. For example, exposure fields in the rows and columns may be staggered or unstaggered, and the exposure fields may be placed in adjacent columns or rows at other than 90 degree angles. The exposure fields may be arranged in rows of exposure fields where every other or other periodic pattern of exposure fields are aligned in a row, for example, not shown. As another example, exposure fields within a row may be straight but the exposure fields may not have a repeating pattern in columns, also not shown.

Exposure time for a wafer 288 is reduced by embodiments of the present invention. The amount of time and space required for overscan and stepping to adjacent exposure fields 203 is reduced. The number of stepping processes is reduced, for example. The distances that are scanned for acceleration and stabilization, in particular, the overscan regions may be reduced by performing the scanning operations, e.g., motion paths 240a and 240b of the wafer support 204 at a constant speed, for example.

Embodiments of the present invention also include novel lithography processes. For example, referring to FIG. 9, in a preferred embodiment, a lithography process includes the steps of providing a workpiece 202, the workpiece 202 comprising rows and columns of exposure fields, and providing a lithography mask 210, the lithography mask 210 comprising a pattern thereon. The exposure fields are exposed using the lithography mask 210 by moving the workpiece 202 along at least one exposure field in a first direction while alternatingly moving the lithography mask 210 in a second direction for every other exposure field in the column, wherein the second direction comprises a direction opposite the first direction. The lithography process includes moving the lithography mask 210 in the first direction for exposure fields between the every other exposure fields in the column, wherein exposure fields are not exposed when the lithography mask 210 is moved in the first direction.

The lithography process may include exposing the exposure fields of the workpiece 202 using the lithography mask 210 by moving the workpiece 202 along at least one exposure field in a column for at least one row, stepping over to an adjacent column of exposure fields at a constant radius R, and moving the workpiece 202 along at least one exposure field in the adjacent column for at least one row. Exposing the exposure fields of the workpiece 202 may comprise moving the workpiece 202 along one exposure field in a column, moving the workpiece 202 along a plurality of exposure fields in the column, or moving the workpiece 202 along every exposure field in the column, as examples. Exposing the exposure fields of the workpiece 202 preferably comprises moving the workpiece 202 at a constant velocity and/or acceleration, for example.

The lithography process may include exposing the exposure fields using the lithography mask 210 by moving the workpiece 202 along an entire column of exposure fields in a second direction while alternatingly moving the lithography mask 210 in the first direction for exposure fields between the every other exposure fields in the column. The lithography mask 210 may be moved in the first direction for the every other exposure fields in the column, wherein exposure fields are not exposed when the lithography mask 210 is moved in the second direction.

The exposing steps are preferably repeated for every column of exposure fields 203. The lithography process may also include stepping over to an adjacent column of exposure fields before repeating the exposing steps for every column of exposure fields. Stepping over to the adjacent column of exposure fields may include stepping over to the adjacent column at a constant radius, in some embodiments. The exposure fields may be exposed using the lithography mask 210 by moving the workpiece 202 along the entire column of exposure fields, which results in a reduction in velocity and/or acceleration changes, and/or reduced centrifugal force of movement between columns of the lithography process, advantageously.

FIG. 9 shows a lithography system 280 in accordance with a preferred embodiment of the present invention. The lithography system 280 includes an illuminator 208 that is adapted to direct energy, such as light or other type of radiation, towards a semiconductor device 288 comprising a workpiece 202 having a layer of photosensitive material 286 disposed thereon. The lithography system 280 includes a projection lens system 206 comprising a first end and a second end opposite the first end, disposed proximate a workpiece 202. A support (not shown) for a lithography mask 210 is disposed between the illuminator 208 and the first end of the projection lens system 206. The support may comprise a pellicle or other support structure for the mask 210, for example. The lithography mask 210 is disposed proximate the projection lens system 206.

The lithography system 280 includes a means 282 for moving the support for the lithography mask during an exposure process, and also at other times, e.g., when an exposure process is not being performed. The means 282 for moving the support for the lithography mask may comprise a motor, a processor, a memory, and software, as examples, although the means 282 may include other components. A support 204 for a semiconductor device 288 is preferably disposed proximate the second end of the projection lens system 206. A means 284 for moving the support 204 for the semiconductor device 288 during the exposure process is disposed proximate the support 204, as shown. The means 284 for moving the support 204 for the semiconductor device 288 may comprise a motor, a processor, a memory, and software, as examples, although the means 284 may include other components. The means 284 for moving the support 204 for the semiconductor device 288 preferably includes a means for stepping the support for the semiconductor device 288 over to an adjacent column of exposure fields at a constant radius, for example, in some embodiments. The means 284 for moving the support 204 for the semiconductor device 288 may be adapted to move the support 204 at a constant velocity and/or acceleration, for example. The means 284 for moving the support 204 and the means 282 for moving the lithography mask 210 are preferably in communication, as shown in phantom, so that the movement of the semiconductor device 288 and the lithography mask 210 may be synchronized.

The means 284 for moving the support 204 for the semiconductor device 288 is adapted to move a semiconductor device 288 along an entire column of exposure fields of the semiconductor device 288 in a first direction, in some embodiments. The means 284 for moving the support 204 for the semiconductor device 288 may be adapted to move the semiconductor device 288 along a portion of a column of exposure fields, e.g., one or more exposure fields within the column, before moving to an adjacent row, in other embodiments. The means 282 for moving the support for the lithography mask is adapted to move a lithography mask 210 alternatingly in a second direction and the first direction for each exposure field in the column while the means 284 for moving the support for the semiconductor device moves a semiconductor device 288 along an entire column of exposure fields in the first direction, wherein the second direction comprises a direction opposite the first direction.

In some embodiments, the means 284 for moving the support for the semiconductor device 288 during the exposure process is adapted to move the support for the semiconductor device 288 in a first direction in a first scan process and then in the second direction in a second scan process for each column of exposure fields before moving to an adjacent column, as shown in FIG. 8. In other embodiments, the means 284 for moving the support for the semiconductor device 288 during the exposure process is adapted to move the support for the semiconductor device 288 in a first scan process for all columns of exposure fields of the semiconductor device 288 and then in a second scan process for all columns of exposure fields of the semiconductor device 288, as shown in FIG. 6.

The lithography system 280 may comprise a means for disposing a fluid (not shown) between the projection lens system 206 and the support 204 for the semiconductor device 288 during the exposure process, e.g., if the lithography system 280 comprises an immersion lithography system. The means for disposing the fluid may comprise an immersion head, for example, coupled to or proximate the second end of the projection lens system 206, although alternatively, the means for disposing the fluid may comprise other types of fluid-providing devices, such as a fluid handler (not shown).

An opaque plate 212 is disposed between the lithography mask 210 and the projection lens system 206, the opaque plate 212 comprising an exposure slit 214 therein. The exposure slit 214 may comprise about 10 mm or less, or other dimensions, and the mask 210 and wafer support 204 are moved in a scanning process while energy is directed through the slit 214.

The illuminator 208 is adapted to expose the workpiece 202 when the lithography mask 210 is moved in the second direction, and not expose the workpiece 202 when the lithography mask 210 is moved in the first direction, in some embodiments. Alternatively, the illuminator 208 may be adapted to expose the workpiece 202 when the lithography mask 210 is moved in the first direction and not when the workpiece 202 is moved in the second direction, or both when the lithography mask 210 is moved in the first direction and also when the workpiece 202 is moved in the second direction. The means 284 for moving the support 204 for the semiconductor device 288 may be adapted to move a semiconductor device 288 along the entire column of exposure fields in the second direction, and the means 282 for moving the support for the lithography mask 210 may be adapted to move a lithography mask 210 alternatingly in the first direction and the second direction for each exposure field in the column while the means 284 for moving the support 204 for the semiconductor device 288 moves a semiconductor device 288 along the entire column of exposure fields in the second direction, exposing the exposure fields that were not exposed when the workpiece 202 was moved in the first direction, for example.

Embodiments of the present invention include methods of manufacturing semiconductor devices 288 using the scanning and lithography methods, and lithography systems described herein. Embodiments of the present invention also include semiconductor devices 288 manufactured using the methods described herein. For example, in one embodiment, a method of manufacturing a semiconductor device 288 includes providing a workpiece 202. The workpiece 202 may include a semiconductor substrate comprising silicon or other semiconductor materials covered by an insulating layer, for example. The workpiece 202 may also include other active components or circuits, not shown. The workpiece 202 may comprise silicon oxide over single-crystal silicon, for example. The workpiece 202 may include other conductive layers or other semiconductor elements, e.g., transistors, diodes, etc. Compound semiconductors, GaAs, InP, Si/Ge, or SiC, as examples, may be used in place of silicon. The workpiece 202 may comprise a silicon-on-insulator (SOI) substrate, for example.

In some embodiments, the workpiece 202 is preferably moved along an entire column of exposure fields in a first direction while alternatingly moving the lithography mask 210 in a second direction and the first direction for each exposure field in the column, the second direction being a direction opposite the first direction. The workpiece 202 is affected with the projection lens system 206 and the lithography mask 210 during the movement of the workpiece 202 in the first direction and during the movement of the lithography mask 210 in the second direction.

In other embodiments, the workpiece 202 may be moved along at least one exposure field in a column for at least one row, and the workpiece 202 is stepped over to an adjacent column of exposure fields at a constant radius. The workpiece 202 may be moved along at least one exposure field in the adjacent column for at least one row, and the workpiece 202 may be affected with the projection lens system 206 and the lithography mask 210 during the movement of the workpiece 202 along the at least one exposure field in the column and in the adjacent column.

The workpiece 202 may include a layer of photosensitive material 286 disposed thereon, and affecting the workpiece 202 may include patterning the layer of photosensitive material 286 using the lithography mask 210. The workpiece 202 may have a material layer disposed thereon (not shown), the layer of photosensitive material 286 being disposed over the material layer. The layer of photosensitive material 286 may be exposed, and affecting the workpiece 202 may include altering the material layer through the patterned layer of photosensitive material 286. Altering the material layer may include etching the material layer, implanting the material layer with a substance, or depositing another material layer over the material layer, as examples, although other methods of altering the material layer may also be used. The material layer may include a conductive material, a semiconductive material, or an insulating material, as examples.

Note that even though a workpiece 202 may be required to be scanned twice in order to expose all exposure fields 203 in some embodiments, advantageously, experimental calculations show that the total scan time to expose an entire workpiece 202 may be reduced by about ⅓ to ¼ with the novel scanning methods of the present invention.

Advantages of embodiments of the invention include providing novel methods of achieving wafer stage acceleration avoidance in lithography exposure tools. Total exposure time of a semiconductor device or wafer 288 is lowered significantly, resulting in a cost savings. The wafer stage 204 is less strained because it is subjected to fewer changes in velocity and acceleration, and less centrifugal force, which further results in improvements in defectivity and overlay, and higher device yields.

Because the wafer stage 204 is moved along each column in a smooth, continuous speed, water confinement between the projection lens system 206 and the semiconductor device 288 is optimized, reducing the possibility of watermark formation. Fewer overscan regions are required for stabilization on a semiconductor device 288, for example, increasing the throughput of semiconductor devices 288.

In embodiments wherein the wafer stage 204 is stepped over to an adjacent column at a constant radius R, a change in acceleration of the wafer stage 204 is minimized. In other embodiments wherein entire columns of exposure fields are scanned at once before stepping over to an adjacent column, acceleration and velocity changes of the wafer stage 204 are advantageously eliminated, for example.

Although embodiments of the present invention are particularly useful in immersion lithography systems, because the formation of watermarks can be avoided, embodiments of the present invention also have useful application in other types of lithography systems wherein a fluid is not disposed between the projection optics and the wafer, for example. Embodiments of the present invention may also be implemented in optical lithography systems, extreme ultraviolet (EUV) lithography systems, electron beam based lithography systems, or non-optical lithography systems, as examples.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of exposing a workpiece, the method comprising:
moving a workpiece along a plurality of exposure fields in a column in a first direction while alternatingly moving a lithography mask in a second direction and the first direction for the plurality of exposure fields in the column, wherein the second direction comprises a direction opposite the first direction.

2. The method according to claim 1, further comprising exposing the workpiece when the lithography mask is moved in the first direction, exposing the workpiece when the lithography mask is moved in the second direction, or exposing the workpiece when the lithography mask is moved in both the first direction and the second direction.

3. The method according to claim 1, further comprising not exposing the workpiece when the lithography mask is moved in the second direction or in the first direction.

4. The method according to claim 1, wherein the column comprises a first column, further comprising moving to an adjacent at least one second column after moving the workpiece along the plurality of exposure fields in the first column, and scanning a plurality of exposure fields in the at least one second column in the second direction while alternatingly moving the lithography mask in the first direction and the second direction for exposure fields in the at least one second column.

5. The method according to claim 4, further comprising repeating moving to an adjacent at least one second column for all columns of the workpiece, and alternating moving the workpiece in the first direction and the second direction for each adjacent at least one second column.

6. The method according to claim 1, wherein moving the workpiece along a plurality of exposure fields in the column in the first direction comprises scanning the entire column.

7. The method according to claim 6, further comprising, after moving the workpiece along the entire column of the plurality of exposure fields in the first direction while alternatingly moving the lithography mask in the second direction and the first direction for the plurality of exposure fields in the column, moving the workpiece along the entire column of the plurality of exposure fields in the second direction while alternatingly moving the lithography mask in the first direction and the second direction for each exposure field in the column, exposing the plurality of exposure fields that were not exposed when the workpiece was moved in the first direction.

8. A lithography process, comprising:
providing a workpiece, the workpiece comprising a plurality of exposure fields arranged in rows and columns;
providing a lithography mask, the lithography mask comprising a pattern thereon; and
exposing the exposure fields of the workpiece using the lithography mask by moving the workpiece along at least one exposure field in a column for at least one row, stepping over to an adjacent column of exposure fields at a constant radius, and moving the workpiece along at least one exposure field in the adjacent column for at least one row.

9. The lithography process according to claim 8, wherein exposing the exposure fields of the workpiece comprises moving the workpiece along one exposure field in the column, moving the workpiece along a plurality of exposure fields in the column, or moving the workpiece along every exposure field in the column.

10. The lithography process according to claim 8, further comprising repeating the exposing step for every exposure field of the workpiece.

11. The lithography process according to claim 8, wherein exposing the exposure fields of the workpiece comprises moving the workpiece at a constant velocity and/or acceleration.

12. A method of manufacturing a semiconductor device, the method comprising:
providing a workpiece;
disposing a projection lens system proximate the workpiece;
disposing a lithography mask proximate the projection lens system;
moving the workpiece along an entire column of exposure fields in a first direction while alternatingly moving the lithography mask in a second direction and the first direction for each exposure field in the column, wherein the second direction comprises a direction opposite the first direction; and
affecting the workpiece with the projection lens system and the lithography mask during the movement of the workpiece in the first direction and during the movement of the lithography mask in the first direction, the second direction, or both the first direction and the second direction.

13. The method according to claim 12, wherein providing the workpiece comprises providing a workpiece having a layer of photosensitive material disposed thereon, and wherein affecting the workpiece comprises patterning the layer of photosensitive material using the lithography mask.

14. The method according to claim 13, wherein providing the workpiece comprises providing a workpiece having a material layer disposed thereon, the layer of photosensitive material being disposed over the material layer, further comprising exposing the layer of photosensitive material, and wherein affecting the workpiece comprises altering the material layer through the patterned layer of photosensitive material.

15. The method according to claim 14, wherein altering the material layer comprises etching the material layer, implanting the material layer with a substance, or depositing another material layer over the material layer.

16. The method according to claim 14, wherein the material layer comprises a conductive material, a semiconductive material, or an insulating material.

17. A semiconductor device manufactured in accordance with the method of claim 16.

18. A method of manufacturing a semiconductor device, the method comprising:
providing a workpiece, the workpiece comprising a plurality of exposure fields arranged in rows and columns;
disposing a projection lens system proximate the workpiece;
disposing a lithography mask proximate the projection lens system;
moving the workpiece along at least one exposure field in a column for at least one row;
stepping the workpiece over to an adjacent column of exposure fields at a constant radius;
moving the workpiece along at least one exposure field in the adjacent column for at least one row; and
affecting the workpiece with the projection lens system and the lithography mask during the movement of the workpiece along the at least one exposure field in the column and in the adjacent column.

19. The method according to claim 18, wherein providing the workpiece comprises providing a workpiece having a layer of photosensitive material disposed thereon, and wherein affecting the workpiece comprises patterning the layer of photosensitive material using the lithography mask.

20. The method according to claim 19, wherein providing the workpiece comprises providing a workpiece having a material layer disposed thereon, the layer of photosensitive material being disposed over the material layer, further comprising exposing the layer of photosensitive material, and wherein affecting the workpiece comprises altering the material layer through the patterned layer of photosensitive material.

21. The method according to claim 20, wherein altering the material layer comprises etching the material layer, implanting the material layer with a substance, or depositing another material layer over the material layer.

22. The method according to claim 20, wherein the material layer comprises a conductive material, a semiconductive material, or an insulating material.

23. A semiconductor device manufactured in accordance with the method of claim 22.

24. A lithography system, comprising:
an illuminator;
a projection lens system comprising a first end and a second end opposite the first end;
a support for a lithography mask disposed between the illuminator and the first end of the projection lens system;
means for moving the support for the lithography mask during an exposure process;
a support for a semiconductor device proximate the second end of the projection lens system; and
means for moving the support for the semiconductor device during the exposure process, wherein the means for moving the support for the semiconductor device is adapted to move a semiconductor device along a column of exposure fields in a first direction, wherein the means for moving the support for the lithography mask is adapted to move a lithography mask alternatingly in a second direction and the first direction for each exposure field in the column while the means for moving the support for the semiconductor device moves a semiconductor device along a column of exposure fields in the first direction, and wherein the second direction comprises a direction opposite the first direction.

25. The lithography system according to claim 24, further comprising means for disposing a fluid between the projection lens system and the support for the semiconductor device during the exposure process.

26. The lithography system according to claim 24, wherein the lithography system comprises an optical lithography system, an immersion lithography system, an Extreme Ultraviolet (EUV) lithography system, an electron beam based lithography system, or a non-optical lithography system.

27. The lithography system according to claim 24, further comprising a means for stepping the support for the semiconductor device over to an adjacent column of exposure fields at a constant radius.

28. The lithography system according to claim 24, wherein the means for moving the support for the semiconductor device during the exposure process is adapted to move the support for the semiconductor device in the first direction in a first scan process and then in the second direction in a second scan process for each column of exposure fields before moving to an adjacent column of exposure fields, or wherein the means for moving the support for the semiconductor device during the exposure process is adapted to move the support for the semiconductor device in a first scan process for all columns of exposure fields of the semiconductor device and then in a second scan process for all columns of exposure fields of the semiconductor device.
